(19) United States
(12) Patent Application Publication
(10) Pub. No.: US 2023/0169684 A1
(43) Pub. Date: Jun. 1, 2023

(54) System and Method Using a System

(71) Applicant: SICK AG, Waldkirch (DE)

(72) Inventors: Heiko STEINKEMPER, Waldkirch (DE); Jens GEBAUER, Waldkirch (DE); Christoph HOFMANN, Waldkirch (DE); Dominik BIRKENMAIER, Waldkirch (DE)

(21) Appl. No.: 17/890,467

(22) Filed: Aug. 18, 2022

(30) Foreign Application Priority Data
Nov. 26, 2021 (DE) 102021131060.1

(51) Int. Cl. G06T 7/80; G06T 7/246

(52) U.S. Cl. CPC G06T 7/80; G06T 7/246; G06T 2207/30204

(57) ABSTRACT

A system and a method using a system for planning a use includes at least one marking, a control and evaluation unit, a database, a display unit, at least one time of flight sensor for a spatial scanning of a real environment, and at least one camera for imaging the real environment. The real environment in a spatial model can be displayed as a virtual environment on the display unit. The marking in the real environment is arranged at a position and has an orientation. The position and the orientation of the marking can be detected at least by the time of flight sensor and the position and orientation of the marking are linked by a virtual sensor model. The virtual sensor model in the spatial model of the virtual environment can be displayed on the display unit at the position and having the orientation of the marking.

The present invention relates to a system and to a method using a system.

Uses or applications, for example in human/robot collaborations (HRC) are often difficult to plan. This not only relates to the robot path per se, for example, but rather in particular to the integration of sensors. These sensors can be both automation sensors and safety sensors. They are always characterized by their effective range, for example the FOV of a camera or the range of a scanner, and by their function, for example a formed protected field. Where a sensor is attached and how it is embedded in the application context is often decisive in an HRC application. The former is often a trial and error procedure, which is time intensive and thus cost intensive. This step can often only be implemented with the real sensors, that is during the integration of the application.

It is an object of the invention to provide an improved system and a method using a system for planning an application.

The object is satisfied by a system for planning a use having at least one marking, having a control and evaluation unit, having a database, having a display unit, and having at least one spatial model of a real environment, and at least one camera for imaging the real environment, wherein the real environment in the spatial model can be displayed as a virtual environment on the display unit, wherein the marking in the real environment is arranged at a position and having an orientation, wherein the position and the orientation of the marking can be detected at least by the camera, wherein the position and orientation of the marking are linked by a virtual sensor model, wherein the virtual sensor model in the spatial model of the virtual environment can be displayed on the display unit at the position and having the orientation of the marking, wherein the virtual sensor model has at least one virtual detection zone, and wherein the virtual detection zone in the spatial model of the virtual environment can be displayed on the display unit.

The object is satisfied by a method using a system for planning a use having at least one marking, having a control and evaluation unit, having a database, having a display unit, and having at least one spatial model of a real environment, and at least one camera for imaging the real environment, wherein the real environment in the spatial model is displayed as a virtual environment on the display unit, wherein the marking in the real environment is arranged at a position and having an orientation, wherein the position and the orientation of the marking is detected at least by the camera, wherein the position and orientation of the marking are linked by a virtual sensor model, wherein the virtual sensor model in the spatial model of the virtual environment is displayed on the display unit at the position and having the orientation of the marking, wherein the virtual sensor model has at least one virtual detection zone, and wherein the virtual detection zone in the spatial model of the virtual environment is displayed on the display unit.

A set of N markings or markers or so-called visual tags is provided, for example. The marking or the markings are positioned or arranged in an environment of a planned use or application. For example, fixedly at an infrastructure, e.g. at a wall or at a work place. The position is, for example, a spatially fixed position and the orientation is a spatially fixed orientation.

The markings are, for example, arranged at manipulators, e.g. at a robot or at mobile platforms. The position is, for example, then a movable variable position and the orientation is a movable variable orientation.

A virtual sensor model that is presented in augmented reality faithful to the orientation with the aid of a display unit or of a mobile end device can now be associated by means of the control and evaluation unit with every marking by a software application an APP application, that is by means of graphical operating software. The detection zone or effective range of the virtual sensor and the sensor function of the virtual sensor in the augmented reality are in particular also presented here. The marking or the markings can, for example, be tracked continuously so that the mobile end device and the marking or markings can be movable. The detection zone can, for example, be a detection field, a protected zone, a protected field, a warning zone, a warning field, or similar.

The environment or an environmental model here also comprises humans that dwell in the real environment, for example an industrial scene. The markings are now used to associate the corresponding sensor function in situ with a located marking or to associate and visualize the position in the correct orientation.

In this process the effective ranges of the virtual sensors do not penetrate any virtual infrastructure, i.e. e.g. walls, floors, or persons are not irradiated in the augmented reality visualization, but are rather photorealistically recorded. An application can thus be planned interactively and/or immersively in a very efficient and transparent manner in a similar manner to “Post-It” notes.

The solution in accordance with the invention improves a planning phase of an application in which as a rule no real sensor is available or no real sensor should yet be used to save costs.

Sensors are only represented by the marking to which specific sensor properties can be assigned. The sensor properties assigned to a marking are visualized in an augmented manner and assist the planning of the application, i.e. an optimum choice of the kind of sensors, of a number of sensors, of an arrangement of the sensors, and/or a configuration or settings of the sensors. A visualization of a synchronization or mutual interference of sensors is provided, for example. An alternating pulsing of sensors can thus be shown, for example.

This augmented or virtual planning goes far beyond the possibilities of a purely digital planning on a PC. It in particular opens up new possibilities of projecting one's thoughts into the application and of thus identifying potentially hazardous situations and to already eliminate them in the planning, especially for the topic of safety in the sense of functional safety or machine safety in complex applications, e.g. in human/robot applications.

Safety experts can thus run through the installation, putting into operation, and/or real work situations and can plan productive work routines together with workers even before purchase. Safety gaps or gaps in the combined protected field of all the planned sensors and thus of the total safety solution can hereby be identified, for example. To visualize this, the measurement and identification takes place of how the markings or markers are disposed relative to one another.

On a change of a marking position or on the addition of a further marking, only the zone around the new position has to be recorded until the algorithm has enough references to correctly reposition the marking in the virtual environment. This could also take place in real time if the end device used for the visualization has the corresponding sensor system.

Accidental and intentional position changes of markings could hereby be automatically recognized, displayed, and, if desired, corrected in the environmental model. If the environmental detection takes place in real time, e.g. via the end device used for the visualization, moving objects can also be taken into account.

After a successful planning, the results can be documented by means of screenshots or videos and can be transferred into the application documentation, e.g. as part of a risk assessment.

The virtual sensors used in the simulation can, for example, be positioned in a shopping basket in a tool of the control and evaluation unit and can be procured by the clients as real sensors.

Sensor configurations formed from the simulation can, for example, likewise be delivered to clients as a parameter file. The simple and fast setup of the real application is thereby made possible and promoted in addition to the simple and fast planning of applications.

The markings attached in the real environment can also serve as installation instructions for an integrator team. For example, assembly instructions, in particular text messages, can be displayed in the virtual environment, for example having the wording: “Please attach a sensor X in the orientation Y shown with a parameter set Z”.

Planning risks are solved in the artificial or augmented reality. The actual integration requires a minimal time effort in this procedure. A downtime of, for example, an existing use for a conversion is thus minimized. Differences between the planning status (e.g. environmental model from CAD data) and the real application are made visible by the virtual sensor behavior. Applications can be replanned very simply and intuitively using this procedure and the best solution found is subsequently implemented in reality with real sensors.

The solution in accordance with the invention permits a support for new digital configuration and ordering processes. A client can virtually plan, store a sensor configuration, and place an order including parameter files directly from the app via, for example, a manufacturer APP including a sensor library. The configuration can alternatively, already be installed on the desired real sensor via the ordering process. An offer for further services such as a risk assessment based on the environmental model, including the sensor arrangement, provided to the client can take place.

The costs of the solution are likewise exactly known with reference to the components used prior to a specific implementation so that a very in-depth cost benefit analysis is possible for the application without a single component or a sensor having been actually procured and attached and furthermore without a specific simulation also having to be programmed again in every plan since it is generated in the augmented solution.

In a further development of the invention, the spatial model is present as a 3D CAD model based on a real environment. The spatial model can be derived from a 3D CAD model and used e.g. as a networked surface.

A global or superior marker or marking is provided, for example, whose pose relevant to the 3D CAD model is known. Starting from this, the markings of the virtual sensors can be calibrated. A graph is, for example, set up internally here, wherein the markers are the nodes and the edges represent the transformations between the markers. This is, for example, also important to inspect the effective ranges of a plurality of sensors at their interfaces.

In accordance with the further development, an application planning by the user is possible in the future production environment, for example a human/robot collaboration (HRC). A user prepares a 3D CAD model or a 3D environmental model in the virtual environment. A simulation and visualization of the safeguarding of the hazard sites take place by positioning tags in the environment that can be flexibly linked via a SICK library to different virtual sensors and their properties. The user can thus virtually plan and simulate his application, store sensor configurations, and place an individualized order via the APP. The client receives preconfigured sensors, including assembly instructions, based on his environmental model. After the installation of the real application, a validation can be made, with the simulation in the virtual environment being compared with the real application. Differences are recognized and can be readjusted.

As in the described human/robot collaboration (HRC) application, the application planning can likewise be carried out by workstations for an autonomous mobile robot application (AMR), for example. A user prepares a 3D CAD model or a 3D environmental model in the virtual environment for this purpose. The safeguarding of the hazard site can be simulated and visualized by positioning markings or markers that are linked to virtual sensors and their properties. The user can thus likewise plan and simulate his application in augmented reality, store sensor configurations, and place an individualized order via the app. Furthermore not only workstations can be simulated and visualized, but also path sections with an autonomous mobile robot use (AMR). For this purpose, a live 3D environmental model can be prepared and potential hazard sites simulated in the route planning.

In a further development, the spatial model is or was formed by means of a 3D sensor. The spatial model can, for example, be formed in advance by means of a 3D sensor. For this purpose, for example, a real environment is spatially scanned and the spatial model is formed in advance. Alternatively, the spatial model can be formed in real time by means of the 3D sensor.

An environmental model can thus be provided in advance. Recording can be done with 3D sensors with a subsequent 3D map generation. Recording can be done with laser scanners with a subsequent map generation.

In a further development of the invention, the position and the orientation of the marking can be detected by the 3D sensor and the camera (7).

A digital end device with the 3D sensor, for example, for this purpose optically localizes the position and orientation of the markings in the environment of the use using the 3D sensor and the camera. In this respect, for example, three different spatial directions and three different orientations, that is six degrees of freedom, of the marking are determined. The 3D sensor here generates the associated virtual environmental model or a situative environmental model.

In this respect, knowledge of the relative location of the marking can also be updated on a location change or an orientation change of the marking. The end devices already mentioned multiple times that are equipped with the camera, the 3D sensor, and the display unit can also be used for this purpose.

The already positioned markings can thus be recognized in the application and can also be associated with a location or coordinates in the environment from the combination of image data of the camera and from generated depth maps of the 3D sensor on the recording of the environment and the generation of the environmental model.

In a further development of the invention, the 3D sensor is a stereo camera or a time of flight sensor.

A digital end device, for example an iPhone 12 Pro or an iPad Pro, with the time of flight sensor, for this purpose, for example, optically localizes the position and orientation of the markings in the environment of the application using the time of flight sensor and the camera. In this respect, for example, three different spatial directions and three different orientations, that is six degrees of freedom, of the marking are determined. The time of flight sensor, for example a LIDAR scanner here generates the associated virtual environmental model or a situative environmental model.

A digital end device, for example a smartphone or a tablet computer, with an integrated stereo camera for this purpose, for example, optically localizes the position and orientation of the markings in the environment of the use using the stereo camera and the camera. In this respect, for example, three different spatial directions and three different orientations, that is six degrees of freedom, of the marking are determined. The stereo camera here generates the associated virtual environmental model or a situative environmental model.

In a further development of the invention, the time of flight sensor is a laser scanner or a 3D time of flight camera.

The environment can, for example, be recorded as a real time environmental model by the time of flight sensor, for example a 3D time of flight camera or a Lidar camera, or a laser scanner. In accordance with the invention, the real time environmental model can be combined with 2D image data from the camera, for example the mobile end device, so that a real time segmentation is carried out on the basis of the depth data. In this manner, for example, a floor, a wall, a work place, and/or a person can be identified.

Transferred to an industrial safety concept and an HRC application planning based on augmented reality, this could look as follows in an example with three markings that each represent a virtual laser scanner.

Two markings are, for example, spatially fixedly arranged at a robot and should detect and safeguard a specific zone around the robot. Provision is made that this zone is likewise input or drawn in the application by a mobile end device and zones are thus identified that are not detected by the safety sensors in their current attachment and configuration. Such zones are e.g. produced behind static objects at which the protected fields are cut off due to the taught environmental data.

The protected fields can also be interrupted or cut off at moving obstacles such as the worker or an AGC if an augmented reality device having a 3D sensor system or a further device delivering 3D data is used. A segmentation of e.g. the person in the color image and a subsequent mapping to 3D data would be provided, for example, to separate taught environmental data and a dynamic object. In principle, markings are also provided at moving machine parts or vehicles.

A correspondence between the markings and the virtual sensors can look as follows, for example:

The data models of virtual sensors are stored in a library of the database, for example. This library, for example, comprises the 3D CAD model, an effective range, and a set of functions for every sensor. In addition, for example, meta data are stored for every sensor; they can, for example, comprise a sensor type (e.g. laser scanner, 3D time of flight camera, etc.), physical connectors (e.g. Ethernet, IO link, etc.), or a performance level. The library or sensor library can be equipped with search filters so that the user can decide which virtual sensors he would like to use for the association (e.g. a 3D time of flight camera with 940 nm wavelength, 3 m range, 70° field of vision, and Ethernet connector). Similar to a morphological box, different sensors can be associated with the markings and are then used for planning the application.

An environmental model can also be provided in advance. Recording can be made with 3D sensors with a subsequent 3D map generation. Recording can be done with laser scanners with a subsequent map generation. It can be derived from a 3D CAD model and used e.g. as a networked surface.

In a further development of the invention, the markings are at least two-dimensional matrix encodings. In this respect, the unique direction and the unique orientation of the marking can be recognized and determined from the two-dimensional matrix encoding. The matrix encoding can optionally comprise the kind of the sensor as well as further properties of the sensor such as a protected field size, a protected field direction, and a protected field orientation. The marking, for example, has a two-dimensional encoding and in addition color information.

The visual markings can be April tags or April markers, for example. They have less information with respect to a QR code and are nevertheless orientation sensitive. April tag markings, for example, have a white border and include a matrix, for example 8×8, therein of black and white fields as the matrix code.

So-called ArUco tags can also be considered. An ArUco tag or ArUco marker is a synthetic square marker that comprises a wide black margin and an inner binary matrix that determines its identifier (ID). The black margin facilitates its fast recognition in the image and the binary encoding enables its identification and the use of error recognition and correction techniques. The size of the marking determines the size of the internal matrix. A marker size of 4×4 consists of 16 bits, for example.

Vuforia markers “Vu-Mark” can also be used. Vuforia markers have a contour, a boundary region, a free spacing region, code elements, and a background region. It is possible and provided that further information can be stored on the tag. E.g.: data sheets, certificates, user manuals, etc.

In a further development of the invention, the markings are at least real 3D models. They can, for example, here be small spatial sensor models of foam or other materials. The marking is here formed via the 3D contour of the sensor model.

In a further development of the invention, the marking is arranged in the real environment by means of a holding device.

Universally suitable suspensions are, for example, provided to be able to position the markings as freely as possible in the application for planning. A modular attachment concept comprising a base plate having the marking is, for example, provided in combination with selectively a magnetic device, an adhesive device, a clamping device, and/or a screw device.

In a further development of the invention, the position and orientation of a second marking is linked to a virtual object, with the virtual object in the spatial model of the environment being displayed on the display unit at the position and having the orientation of the second marking.

The virtual object can, for example, be a virtual machine, a virtual barrier, a virtual store, virtual material, virtual workpieces, or similar.

The movements, routes, interventions, etc. of a human can be transferred into a simulation or the virtual environment by means of a similar technique. For this purpose, markings or markers can be attached to the joints of the human and the movements can be recorded and displayed.

In a further development of the invention, the display unit is a smartphone, a tablet computer, augmented reality glasses/headset, or virtual reality glasses/headset.

Device or systems can thus be considered as mobile end devices that are equipped with at least one camera and a possibility for visualization.

In a further development of the invention, the markings have at least one transponder.

Provision is made in accordance with the further development that the visual markings are additionally provided with radio location, for example using a UWB technique. AirTags from Apple can be used here, for example. An AirTag is designed such that it works as a key finder and helps to find keys and other articles with the aid of ultra wideband technology (UWB). The exact distance from and direction to the AirTag being looked for can be displayed by the U1 chip developed by Apple.

In a further development of the invention, the virtual sensor model is configurable, with the configuration of the virtual sensor model being able to be transferred to the real sensor.

Sensor configurations of the virtual sensor, e.g. a protected field size of a virtual laser scanner, can be stored using the environmental model and the desired effective range of virtual sensors spanned over the markings and, for example, provided to a client as part of the ordering process for real sensors. In addition to the simple and fast planning of applications, the sensor configuration likewise supports the setting up of the real application.

In a further development of the invention, at least one virtual solution is transferred to a solution after a virtual planning. A virtual continuation of the planning in a simulation is thereby possible.

Subsequent to the virtual planning, one or more virtual solutions can be transferred to a simulation. Both process-relevant parameters, for example speeds, components per hour, etc. and safety-directed parameters, for example detection zones, detection fields, protected fields, warning fields, speeds, routes, and/or interventions by workers can now be varied and simulated in the simulation. The safety concept can thereby be further validated, on the one hand, and a productivity and an added value of the safety solution can be quantified and compared, on the other hand. Provision is, for example, made that the exact sensor position and sensor orientation are optimized in the virtual planning. The parameters of the sensors can subsequently again be optimized.

The invention will also be explained in the following with respect to further advantages and features with reference to the enclosed drawing and to embodiments. The Figures of the drawing show in:

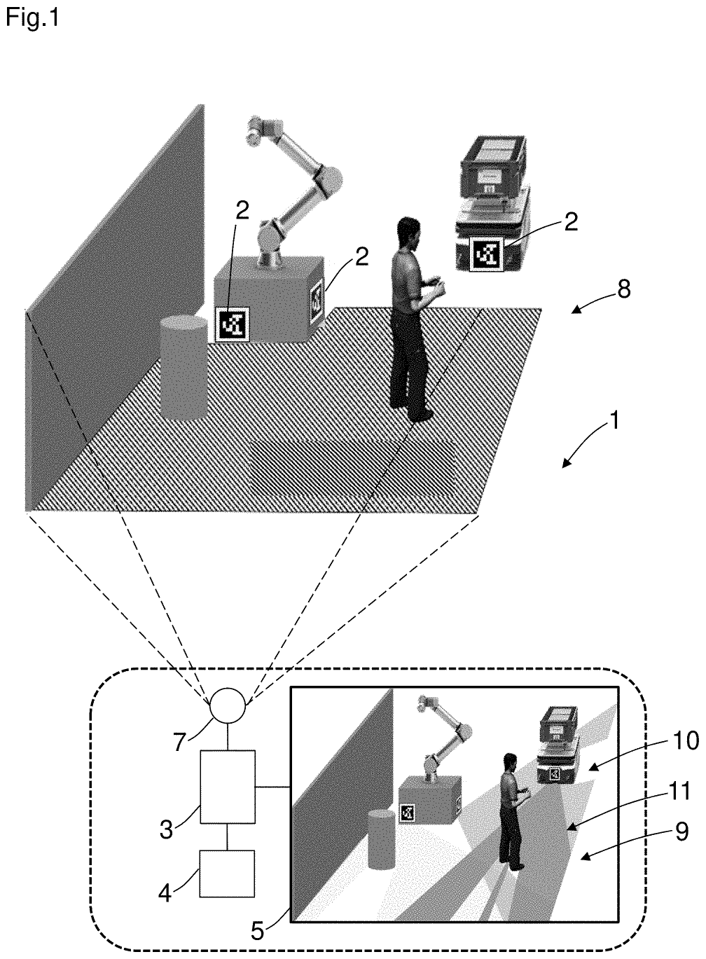

FIG. 1 a system for planning a use with at least one marking;

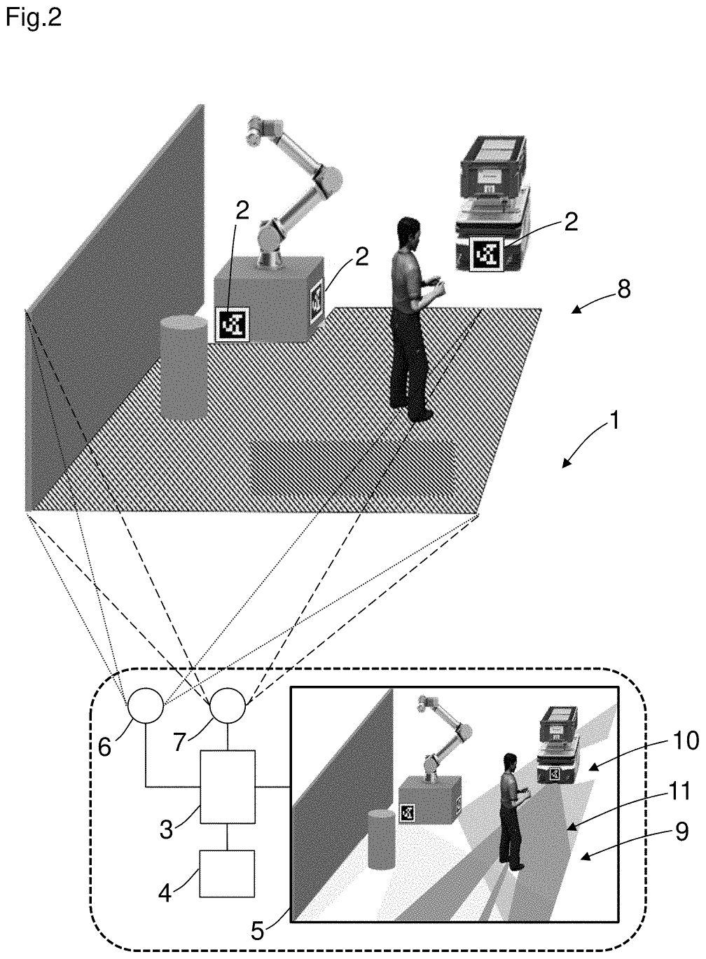

FIG. 2 a system for planning a use with at least one marking;

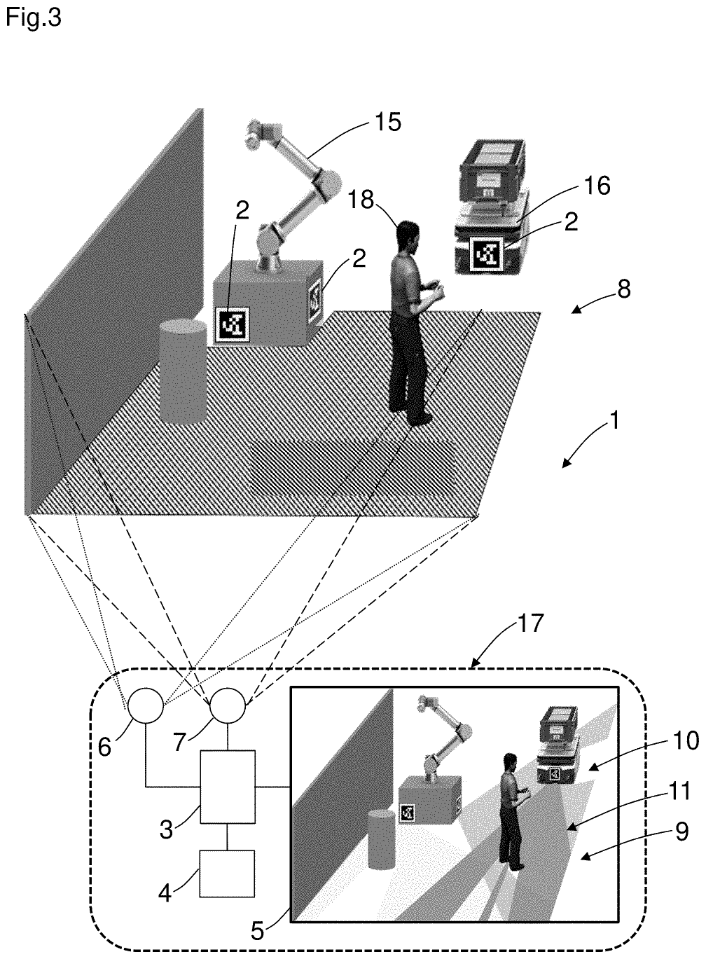

FIG. 3 a further system for planning a use with at least one marking;

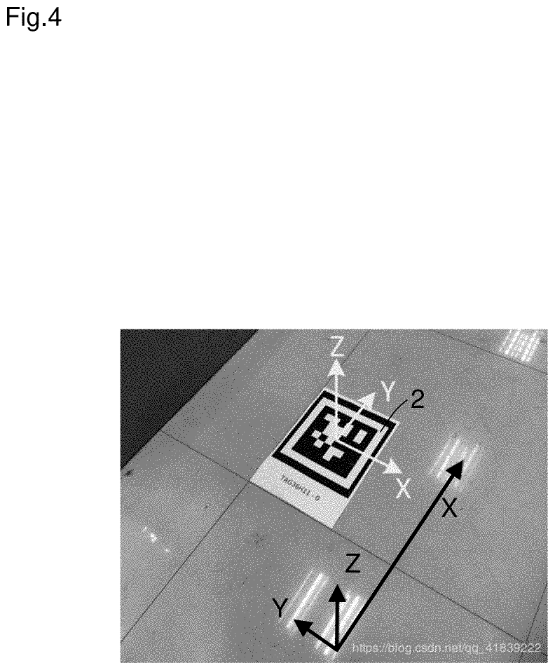

FIG. 4 an exemplary marking;

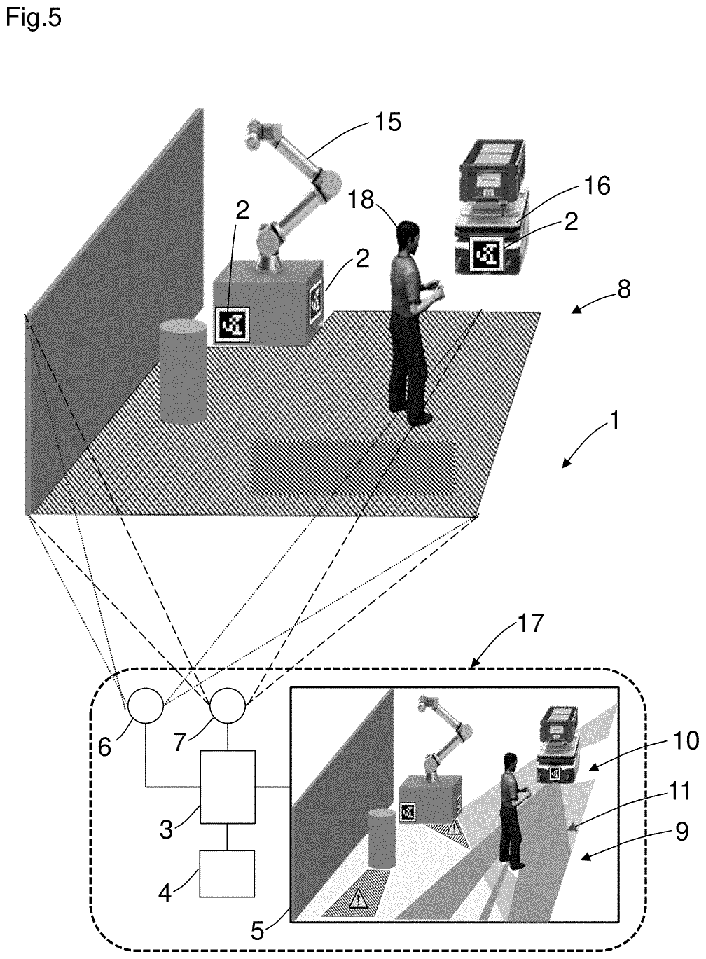

FIG. 5 a further system for planning a use with at least one marking.

In the following Figures, identical parts are provided with identical reference numerals.

FIG. 1 shows a system 1 for planning a use having at least one marking 2, having a control and evaluation unit 3, having a database 4, having a display unit 5, and having at least one spatial model of a real environment, and at least one camera 7 for imaging the real environment 8, wherein the real environment 8 in the spatial model can be displayed as a virtual environment 9 on the display unit 5, wherein the marking 3 in the real environment 8 is arranged at a position and having an orientation, wherein the position and the orientation of the marking 2 can be detected at least by the camera 7, wherein the position and orientation of the marking 2 are linked by a virtual sensor model 10, wherein the virtual sensor model 10 in the spatial model of the virtual environment 9 can be displayed on the display unit at the position and having the orientation of the marking 2, wherein the virtual sensor model 10 has at least one virtual detection zone 11, and wherein the virtual detection zone 11 in the spatial model of the virtual environment 9 can be displayed on the display unit 5.

FIG. 2 shows a system 1 for planning a use having at least one marking 2, having a control and evaluation unit 3, having a database 4, having a display unit 5, and having at least one time of light sensor 6 for a spatial scanning of a real environment, and at least one camera 7 for imaging the real environment, wherein the real environment in the spatial model can be displayed as a virtual environment 9 on the display unit 5, wherein the marking 2 in the real environment 8 is arranged at a position and having an orientation, wherein the position and the orientation of the marking 2 can be detected by the time of flight sensor 6, wherein the position and orientation of the marking 2 are linked by a virtual sensor model 10, wherein the virtual sensor model 10 in the spatial model of the virtual environment 9 can be displayed on the display unit 5 at the position and having the orientation of the marking 2, wherein the virtual sensor model 10 has a virtual protected field 11, and wherein the virtual protected field 11 in the spatial model of the virtual environment 9 can be displayed on the display unit 5.

FIG. 3 shows a system in accordance with FIG. 2. A set of N markings 2 or markers or so-called visual tags is provided, for example. The marking 2 or the markings 2 are positioned or arranged in an environment of a planned use or application. For example, fixedly at an infrastructure, e.g. at a wall or at a work place. The position is, for example, a spatially fixed position and the orientation is a spatially fixed orientation.

The markings 2 are, for example, arranged at manipulators, e.g. at a robot 15 or at mobile platforms 16. The position is, for example, then a movable variable position and the orientation is a movable variable orientation.

A virtual sensor model 10 that is presented in augmented reality faithful to the orientation with the aid of a display unit 5 or of a mobile end device can now be associated by means of the control and evaluation unit 3 with every marking 2 by software or APP. The effective range of the virtual sensor and the sensor function of the virtual sensor in the augmented reality are in particular also presented here. Provision can also be made to be able to set the relative translation and orientation between the marker and the augmented object on the digital end device.

A digital end device 17 with the time of flight sensor 6, for example, for this purpose optically localizes the position and orientation of the markings 2 in the environment of the use using the time of flight sensor 6 and the camera 7. In this respect, for example, three different spatial directions and three different orientations, that is six degrees of freedom, of the marking 2 are determined. The time of flight sensor 6, for example a LIDAR scanner here generates the associated virtual environmental model or a situative environmental model.

The environment or an environmental model here also comprises persons 18, for example, that dwell in the real environment, for example an industrial scene. The markings 2 are now used to associate the corresponding sensor function in situ with a located marking 2 or to associate and visualize the position in the correct orientation.

In this process the effective ranges of the virtual sensors 10 do not penetrate any virtual infrastructure, i.e. e.g. walls, floors, or persons 18 are not irradiated in the augmented reality visualization, but are rather photorealistically recorded. An application can thus be planned interactively and/or immersively in a very efficient and transparent manner in a similar manner to “Post-It” notes.

Sensors are only represented by the marking 2 to which specific sensor properties can be assigned. The sensor properties assigned to a marking 2 are visualized in an augmented manner.

In this respect, knowledge of the relative location of the marking 2 can also be updated on a location change or an orientation change of the marking 2.

The already positioned markings 2 can thus be recognized in the application and can also be associated with a location or coordinates in the environment from the combination of image data of the camera 7 and from generated depth maps of the time of flight sensor 6 on the recording of the environment and the generation of the environmental model.

On a change of a marking position or on the addition of a further marking 2, only the zone around the new position has to be recorded until the algorithm has enough references to correctly reposition the marking 2 in the virtual environment. This could also take place in real time if the end device 17 used for the visualization has the corresponding sensor system.

If the environmental detections takes place in real time, e.g. via the end device used for the visualization, moving objects can also be taken into account.

After a successful planning, the results can be documented by means of screenshots or videos and can be transferred into the application documentation, e.g. as part of a risk assessment.

The virtual sensors 10 used in the simulation can, for example, be positioned in a shopping basket in a tool of the control and evaluation unit 3 and can be obtained by the clients as real sensors.

Sensor configurations formed from the simulation can, for example, likewise be delivered to clients as a parameter file. The simple and fast setup of the real application is thereby made possible and promoted in addition to the simple and fast planning of applications.

The markings 2 attached in the real environment 8 can also serve as installation instructions for an integrator team. For example, assembly instructions, in particular text messages, can be displayed in the virtual environment 9, for example having the wording: “Please attach a sensor X in the orientation shown Y with a parameter set Z”.

Subsequent to the virtual planning, one or more virtual solutions can be transferred to a simulation. Both process-relevant parameters, for example speeds, components per hour, etc. and safety-directed parameters, for example, protected fields, speeds, routes, and/or interventions by workers can now be varied and simulated in the simulation. The safety concept can thereby be further validated, on the one hand, and a productivity and an added value of the safety solution can be quantified and compared, on the other hand.

An application planning by the user is possible in the future production environment, for example a human/robot collaboration (HRC). A user prepares a 3D environmental model in the virtual environment 9. A simulation and visualization of the safeguarding of the hazard sites takes place by positioning markings 2 in the environment that can be flexibly linked via a SICK library to different virtual sensors and their properties. The user can thus virtually plan and simulate his application, store sensor configurations, and place an individualized order via the APP. The client receives preconfigured sensors, including assembly instructions, based on his environmental model. After the installation of the real application, a validation can be made, with the simulation in the virtual environment 9 being compared with the real application. Differences are recognized and can be readjusted.

As in the described human/robot collaboration (HRC) application, the application planning can likewise be carried out by workstations for an autonomous mobile robot application (AMR), for example. A user prepares a 3D model in the virtual environment 9 for this purpose. The safeguarding of the hazard site can be simulated and visualized by positioning markings 2 or markers that are linked to virtual sensors 10 and their properties. The user can thus likewise plan and simulate his application in augmented reality, store sensor configurations, and place an individualized order via the app. Furthermore not only workstations can be simulated and visualized, but also path sections with an autonomous mobile robot (AMR). For this purpose, a live 3D environmental model can be prepared and potential hazard sites simulated in the route planning.

In accordance with FIG. 3, the time of flight sensor 6 is, for example, a laser scanner or a 3D time of flight camera.

Sensor configurations of the virtual sensor 10, e.g. a protected field size of a virtual laser scanner, can be stored using the environmental model and the desired effective range of virtual sensors 10 spanned over the markings 2 and, for example, provided to a client as part of the ordering process for real sensors. In addition to the simple and fast planning of applications, the sensor configuration likewise supports the setting up of the real application.

In accordance with FIG. 3, for example, two markings 2 are, for example, spatially fixedly arranged at a robot 15 and should detect and safeguard a specific zone around the robot 15. Provision is, for example, made that this zone is likewise input or drawn in the application by a mobile end device 17 and zones are thus identified that are not detected by the safety sensors in their current attachment and configuration. Such zones are e.g. produced behind static objects at which the protected fields are cut off due to the taught environmental data. As shown in FIG. 4, warning notices, for example symbolically with an exclamation mark, can be displayed, for example, in the virtual environment.

The protected fields can also be interrupted or cut off at moving obstacles such as the person 18 or the mobile platform 16. In principle, markings 2 are also provided at moving machine parts or vehicles.

A correspondence between the markings 2 and the virtual sensors 10 can look as follows, for example:

The data models of virtual sensors 10 are stored in a library of the database 4, for example. This library, for example, comprises the 3D CAD model, an effective range, and a set of functions for every sensor. In addition, for example, meta data are stored for every senor; they can, for example, comprise a sensor type (e.g. laser scanner, 3D time of flight camera, etc.), physical connectors (e.g. Ethernet, IO link, etc.), or a performance level. The library or sensor library can be equipped with search filters so that the user can decide which virtual sensors 10 he would like to use for the association (e.g. a 3D time of flight camera with 940 nm wavelength, 3 m range, 70° field of vision, and Ethernet connector). Similar to a morphological box, different sensors can be associated with the markings and are then used for planning the application.

In accordance with FIG. 3 and FIG. 4, the markings 2 are two-dimensional matrix encodings. In this respect, the unique direction and the unique orientation of the marking 2 can be recognized and determined from the two-dimensional matrix encoding. The matrix encoding can optionally comprise the kind of the sensor as well as further properties of the sensor such as a protected field size, a protected field direction, and a protected field orientation.

In accordance with FIG. 3, the marking 2 is arranged in the real environment by means of a holding device.

Universally suitable suspensions are, for example, provided to be able to position the markings 2 as freely as possible in the application for planning. A modular attachment concept comprising a base plate having the marking is, for example, provided in combination with selectively a magnetic device, an adhesive device, a clamping device, and/or a screw device.

For example the position and orientation of a second marking 2 is linked to a virtual object, with the virtual object in the spatial model of the environment being displayed on the display unit at the position and having the orientation of the second marking 2.

The virtual object can, for example, be a virtual machine, a virtual barrier, a virtual store, virtual material, virtual workpieces, or similar.

The movements, routes, interventions, etc. of a person 18 can be transferred into a simulation or the virtual environment by means of a similar technique. For this purpose, markings 2 or markers can be attached to the joints of the person 18 and the movements can be recorded and displayed.

In accordance with FIG. 3 the display unit is, for example, a smartphone, a tablet computer, augmented reality glasses/headset, or virtual reality glasses/headset.

Devices or systems can thus be considered as mobile end devices 17 that are equipped with at least one camera and a possibility for visualization.

In accordance with FIG. 3, the markings 2 have for example a transponder.

Provision is, for example, made that the visual markings are additionally provided with radio location, for example using a UWB technique.

### REFERENCE NUMERALS

1 system

2 marking

3 control and evaluation unit

4 database

5 display unit

6 3D sensor

7 camera

8 real environment

9 virtual environment

10 virtual sensor model/virtual sensor

11 virtual protected field

15 robot

16 mobile platforms

17 digital end device

18 person

1. A system for planning a use, the system comprising at least one marking, a control and evaluation unit, a database, a display unit, at least one spatial model of a real environment, and at least one camera for imaging the real environment;
wherein the real environment in the spatial model can be displayed as a virtual environment on the display unit;
wherein the marking in the real environment is arranged at a position and having an orientation;
wherein the position and the orientation of the marking can be detected at least by the camera;
wherein the position and orientation of the marking are linked to a virtual sensor model;
wherein the visual sensor model in the spatial model of the virtual environment can be displayed at the display unit at the position and having the orientation of the marking;
wherein the virtual sensor model has at least one virtual detection zone, wherein the virtual detection zone in the spatial model of the virtual environment can be displayed on the display unit.

2. The system in accordance with claim 1, wherein the spatial model is present as a CAD model on the basis of a real environment.

3. The system in accordance with claim 1, wherein the spatial model is formed or was formed by means of a 3D sensor.

4. The system in accordance with claim 3, wherein the position and the orientation of the marking can be detected by the 3D sensor and the camera.

5. The system in accordance with claim 3, wherein the 3D sensor is a stereo camera or a time of flight sensor.

6. The system in accordance with claim 1, wherein the time of flight sensor is a laser scanner or a is a 3D time of flight camera.

7. The system in accordance with claim 1, wherein the markings are at least two-dimensional matrix encodings.

8. The system in accordance with claim 1, wherein the markings are at least real 3D models.

9. The system accordance with claim 1, wherein the marking is arranged at the real environment by means of a holding device.

10. The system in accordance with claim 1, wherein the position and orientation of a second marking is linked to a virtual object, with the virtual object in the spatial model of the virtual environment being displayed on the display unit at the position and having the orientation of the second marking.

11. The system in accordance with claim 1, wherein the display unit is a smartphone, a tablet computer, augmented reality glasses/headset, or virtual reality glasses/headset.

12. The system in accordance with claim 1, wherein the markings have at least one transponder.

13. The system in accordance with claim 1, characterized in that the virtual sensor model is configurable, with the configuration of the virtual sensor model being able to be transferred to the real sensor.

14. The system in accordance with claim 1, characterized in that at least one virtual solution is transferred to a simulation after a virtual planning.

15. A method using a system for planning a use, the system comprising at least one marking, a control and evaluation unit, a database, a display unit, at least one spatial model of a real environment, and at least one camera for imaging the real environment;
wherein the real environment in the spatial model is displayed as a virtual environment on the display unit;
wherein the marking in the real environment is arranged at a position and having an orientation;
wherein the position and the orientation of the marking are detected at least by the camera;
wherein the position and orientation of the marking are linked to a virtual sensor model;
wherein the visual sensor model in the spatial model of the virtual environment can be displayed at the display unit at the position and having the orientation of the marking;
wherein the virtual sensor model has at least one virtual detection zone, wherein the virtual detection zone in the spatial model of the virtual environment is displayed on the display unit.
